(19) United States
(12) Patent Application Publication
(10) Pub. No.: US 2023/0148333 A1
(43) Pub. Date: May 11, 2023

(54) PARAMETER-REDUCED CALIBRATION WORKFLOW FOR SUBSIDENCE MAP INPUT IN STRATIGRAPHIC MODELS

(71) Applicant: SAUDI ARABIAN OIL COMPANY, Dhahran (SA)

(72) Inventors: Hussain Alqattan, Hofuf (SA); Mokhles Mezghani, Dhahran (SA)

(73) Assignee: SAUDI ARABIAN OIL COMPANY, Dhahran (SA)

(21) Appl. No.: 17/453,954

(22) Filed: Nov. 8, 2021

(51) Int. Cl. G06F 30/20

(52) U.S. Cl. CPC G06F 30/20

(57) ABSTRACT

Methods and systems for calibrating a subsidence map are disclosed. The method includes selecting a stratigraphic model that represents a geological formation and defining the subsidence map with a first set of variable values. The method further includes obtaining target outputs measured from the geological formation. The method still further includes determining first model outputs from the stratigraphic model by inputting the subsidence map with the first set of variable values into the stratigraphic model and determining a first residual between the target outputs and the first model outputs using an objective function.

### BACKGROUND

Stratigraphic models may be used to model geological processes over geological time. Stratigraphic models may be valuable to the oil and gas industry if used to predict attributes of hydrocarbon resources such as volume, type, and location in the present and future. Accurate stratigraphic model predictions rely, at least in part, on accurate subsidence maps, where subsidence may be defined as the rate at which the Earth's surface is settling or sinking toward the center of the Earth. However, it may be challenging to accurately measure subsidence due to the complex interplay between subsidence mechanisms. Thus, it may be pragmatic to adapt subsidence maps iteratively until expected stratigraphic model predictions are obtained to gain confidence that additional stratigraphic model predictions, such as attributes of hydrocarbon resources, are accurate.

### SUMMARY

This summary is provided to introduce a selection of concepts that are further described below in the detailed description. This summary is not intended to identify key or essential features of the claimed subject matter, nor is it intended to be used as an aid in limiting the scope of the claimed subject matter.

In general, in one aspect, embodiments relate to a method of calibrating a subsidence map. The method includes selecting a stratigraphic model that represents a geological formation and defining the subsidence map with a first set of variable values. The method further includes obtaining target outputs measured from the geological formation. The method still further includes determining first model outputs from the stratigraphic model by inputting the subsidence map with the first set of variable values into the stratigraphic model and determining a first residual between the target outputs and the first model outputs using an objective function.

In general, in one aspect, embodiments relate to a non-transitory computer readable medium storing instructions executable by a computer processor. The instructions include functionality for receiving a stratigraphic model that represents a geological formation and receiving a subsidence map with a first set of variable values. The instructions further include receiving target outputs measured from the geological formation. The instructions still further include determining first model outputs from the stratigraphic model by inputting the subsidence map with the first set of variable values into the stratigraphic model and determining a first residual between the target outputs and the first model outputs using an objective function.

In general, in one aspect, embodiments relate to a system including a seismic acquisition system, a geodetic surveying system, and a computer system configured to receive a stratigraphic model based on geological formation data acquired using the seismic acquisition system. The computer system is further configured to receive a subsidence map with a first set of variable values based on topographical data acquired using the geodetic surveying system and receive target outputs based on the geological formation data acquired using the seismic acquisition system. The computer system is further configured to determine first model outputs from the stratigraphic model by inputting the subsidence map with the first set of variable values into the stratigraphic model. The computer system is still further configured to determine a first residual between the target outputs and the first model outputs using an objective function.

Other aspects and advantages of the claimed subject matter will be apparent from the following description and the appended claims.

### BRIEF DESCRIPTION OF DRAWINGS

Specific embodiments of the disclosed technology will now be described in detail with reference to the accompanying figures. Like elements in the various figures are denoted by like reference numerals for consistency.

FIG. 1A depicts a geological formation before subsidence.

FIG. 1B depicts a geological formation after subsidence.

FIG. 2 shows a flowchart in accordance with one or more embodiments.

FIG. 3A depicts a subsidence map defined using a pilot points method in accordance with one or more embodiments.

FIG. 3B depicts a subsidence map defined using a weighted linear combination method in accordance with one or more embodiments.

FIG. 4A shows changes in variable values in accordance with one or more embodiments.

FIG. 4B shows a reduced residual as iteration number increases in accordance with one or more embodiments.

FIG. 5 depicts a computer system in accordance with one or more embodiments.

### DETAILED DESCRIPTION

In the following detailed description of embodiments of the disclosure, numerous specific details are set forth in order to provide a more thorough understanding of the disclosure. However, it will be apparent to one of ordinary skill in the art that the disclosure may be practiced without these specific details. In other instances, well-known features have not been described in detail to avoid unnecessarily complicating the description.

Throughout the application, ordinal numbers (e.g., first, second, third, etc.) may be used as an adjective for an element (i.e., any noun in the application). The use of ordinal numbers is not to imply or create any particular ordering of the elements nor to limit any element to being only a single element unless expressly disclosed, such as using the terms “before”, “after”, “single”, and other such terminology. Rather, the use of ordinal numbers is to distinguish between the elements. By way of an example, a first element is distinct from a second element, and the first element may encompass more than one element and succeed (or precede) the second element in an ordering of elements.

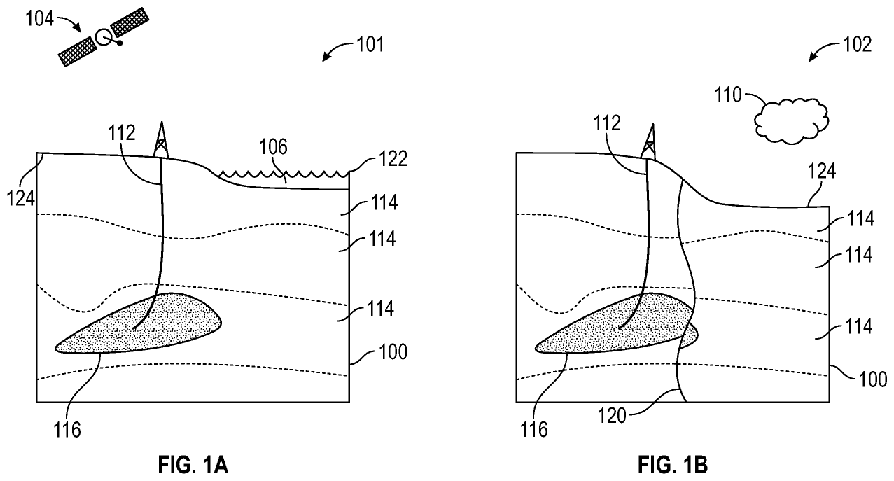

FIGS. 1A and 1B depict a geological formation (100) before subsidence (101) and after subsidence (102). Subsidence may be d as the settling or sinking of the Earth's surface toward the center of the Earth. Subsidence may be measured using various techniques as would be known by a person skilled in the art. One such technique involves using a geodetic survey system (104), which uses known fixed points and corrects for Earth's curvature to estimate subsidence over areas of the Earth.

Mechanisms of subsidence include man-made processes and natural processes. FIGS. 1A and 1B depict man-made processes that may promote subsidence including water extraction and hydrocarbon removal. Subsidence due to water extraction may occur as water (106) is removed for use or storage. Remaining water may then evaporate (110) to leave sediment dry and, thus, lower than before water extraction. Alternatively, hydrocarbon removal by a wellbore (112) may promote subsidence of sedimentary layers (114) as a hydrocarbon reservoir (116) is drained and equilibrium pressure is lost. Further, subsidence may promote creation of a fault (120), i.e., a discontinuity within a sedimentary layer (114). Subsidence due to natural processes include rock dissolution, rock compaction, plate tectonic activity, and other natural disasters. Rock dissolution may occur as rocks with high salt content, such as limestone, dissolve due to precipitation or some other fluid flow and, in turn, neighboring sedimentary layers (114) collapse. Alternatively, rock compaction may promote subsidence due to the weight of overlying sedimentary layers (114), i.e., overburden layers. Plate tectonic activity may occur when plates diverge, converge, or transform relative to one another to create faults (120) in sedimentary layers (114). One type of plate tectonic convergence includes earthquakes. Lastly, other natural disasters such as volcanic eruptions may cause subsidence due to the outflowing of magma from Earth's mantle.

Modeling subsidence may be valuable when input into stratigraphic models, which predict changes in sedimentary layers (114) over geological time. Of particular interest may be using stratigraphic models to predict changes in sediment position and composition to locate sediment that contains hydrocarbon resources. Sediment position may be driven by both subsidence and eustasy, where eustasy may be defined as changes in sea level (122). Sediment may only be allowed to move to a particular position if space is available for that sediment to exist. This space may be referred to as accommodation space and may be defined as the space between sea level (122) and the adjacent topography (124). Adjacent topography (124) may represent the sea floor or continental landscape. Positive accommodation space exists when the adjacent topography (124) is below sea level (122) and, thus, sediment may be allowed to move into the accommodation space. Alternatively, negative accommodation space exists when the adjacent topography (124) is above sea level (122) and, thus, sediment may not be allowed to move into the accommodation space.

A subsidence map may be a primary input that drives accommodation space and thus, sediment position in stratigraphic models. A subsidence map may be defined in the same domain as the stratigraphic model (i.e., in two or three dimensions) or as a domain subset of the stratigraphic model. Further, a subsidence map may be defined using the same grid structure as the stratigraphic model (i.e., structured or unstructured). One embodiment of a structured map assigns a number value to each square or cubic unit in the map. Alternatively, embodiments of an unstructured map assign a number value to each triangular unit or node following triangulation of the modeled topography (124). Each number value within a subsidence map quantifies the vertical rate of change of the topography (124) over geological time. Challenges arise in subsidence map calibration due to, at least in part, the complex interplay between subsidence mechanisms that must be considered upon map creation.

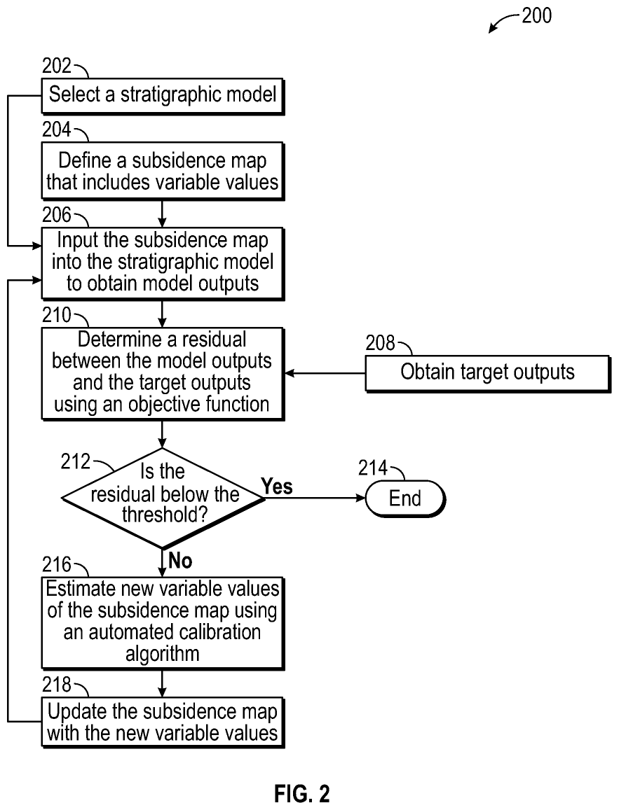

FIG. 2 describes a methodology (200), in accordance with one or more embodiments, to calibrate a subsidence map. In step 202, a stratigraphic model is selected that mathematically models the topography (124) and sedimentary layers (114) in a geological formation (100) over geological time. Geological time may be in the past, present, and/or future. The stratigraphic model may predict changes in sediment thickness, sediment volume, accommodation space, and rock type due to subsidence mechanisms as well as due to erosion and accumulation mechanisms, at least in part.

In step 204, a subsidence map is defined using a pilot points method (300) or a weighted linear combination method (302) as described in more detail below. The subsidence map may be of the same structure as the stratigraphic model. The subsidence map may be a subset of the domain of the stratigraphic model.

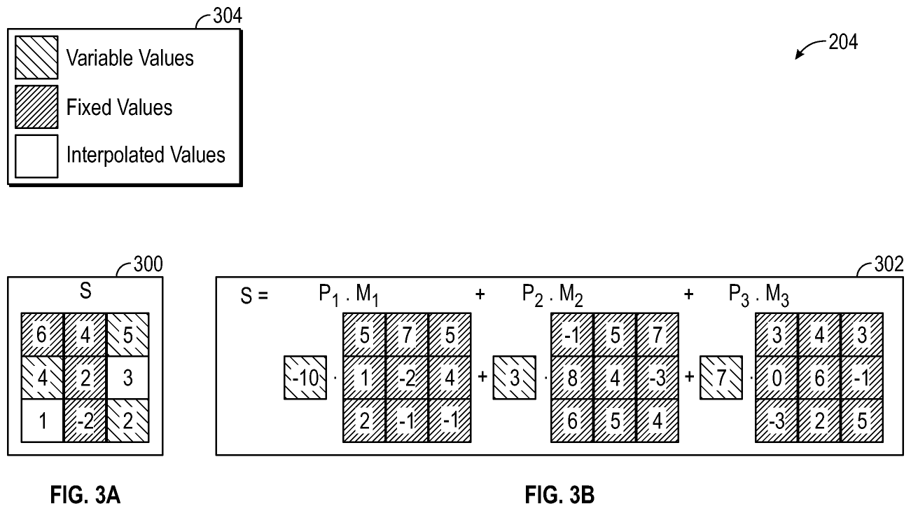

The pilot points method (300) may be considered primarily physical in nature such that subsidence map values represent physically reasonable vertical rates of change of the topography (124) being modeled. Subsidence map number values may be selected randomly within a physically reasonable range based on geodetic survey data along with assumptions such as lateral homogeneity. A subsidence map using the pilot points method (300) includes three types of number values: fixed values, variable values, and interpolated values. Fixed values may have high confidence and remain unchanged throughout the methodology (200). Alternatively, variable values may have low confidence and be changed over the course of the methodology (200). Lastly, interpolated values may be interpolated based on the fixed values and the variable values. Interpolation methods may be performed by a number of methods known to a person of ordinary skill in the art without departing from the scope of the invention. For example, interpolation methods may include kriging (sometimes referred to as Wiener-Kolmogorov prediction) and inverse distance weighting. FIG. 3A shows one embodiment of a pilot points method (300) used to create a subsidence map, S. In this embodiment, the subsidence map, S, is a 3×3 structured matrix with variable, fixed, and interpolated values as shown by the key (304). The variable values, again, may change over the course of the methodology (200) and in this step may be referred to as the first set of variable values of the subsidence map. The interpolated values may also change over the course of the methodology (200) if the variable values change as the interpolated values are dependent on variable values and fixed values. In this step, the interpolated values may be referred to as the first set of interpolated values.

Alternatively, the weighted linear combination method (302) may be primarily phenomenological in nature such that subsidence map values may not be considered physically reasonable based on geodetic survey data of the topology (124) being modeled. Instead, subsidence map values are selected with the aim of producing anticipated stratigraphic model outputs, hereinafter referred to as “target outputs”, as measured from the geological formation (100). This subsidence map is a linear combination of random matrices, Mᵢ, as shown by:

Σᵢ₌₁ⁿPᵢMᵢ Equation (1)

where the weights, Pᵢ, may be fixed or variable values and Mᵢ may include fixed, variable, and/or interpolated values. FIG. 3B shows one embodiment of a weighted linear combination method (302) used to create a 3×3 structured subsidence map, S. In this embodiment, each number value within each of the three random matrices, M₁, M₂, M₃, are fixed values. The weights, P₁, P₂, P₃, are the variable values that may be changed over the course of the methodology (200) as shown by the key (304) and, in this step, may be referred to as the first set of variable values of the subsidence map. The number values within the random matrices, Mᵢ, may be normalized or may not be normalized. FIG. 3B shows one embodiment of non-normalized, random matrices, Mᵢ.

Returning to FIG. 2, in step 206, the subsidence map with the first set of variable values is input into the stratigraphic model. At least one first stratigraphic model output (hereinafter also “first model output(s)”) may be output from the stratigraphic model. The first model outputs may be of the same structure as the subsidence map and the stratigraphic model. The first model outputs may be a domain subset of the subsidence map and/or the stratigraphic model. Types of first model outputs include one or more of a sediment thickness map, a sediment gradient map, a sediment volume map, and a rock classification map.

In step 208, one or more target outputs are measured from the geological formation (100). Topographical data, including subsidence data, may come from a geodetic survey system (104) and sedimentary data may come from a seismic survey system, wireline data, and/or rock core samples. Types of target outputs include one or more of a sediment thickness map, a sediment gradient map, a sediment volume map, and a rock classification map. The structure of the target output may be the same as the stratigraphic model but may be a domain subset of the stratigraphic model. The types of target outputs may be the same as the first model outputs.

In step 210, the first model outputs and the target outputs are compared using, for example, an objective function. The objective function may be a mathematical equation that calculates the overall difference or residual between the first model outputs and the target outputs. Calculating the residual may be performed by any of a number of methods known to a person of ordinary skill in the art without departing from the scope of the invention. For example, objective functions that may be used include a sum of square difference equation, a mean absolute difference equation, a least absolute difference equation, and a mean percentage difference equation. Lastly, in some embodiments, a regularization term or penalty term may be included in the objective function to weight the residual.

The first model outputs and target outputs may be compared using a plurality of embodiments. In this step, the residual will be referred to as the first residual. In one embodiment, the first residual between one first model output and one target output of the same structure, domain, and type may be directly calculated using the objective function. In another embodiment, a residual may be calculated between one first model output and one target output of the same structure and domain for each type and the residuals summed. In still another embodiment, a plurality of first model outputs may be normalized and summed and a plurality of target outputs may be normalized and summed prior to calculating the first residual between the two normalized summations. In this embodiment, the plurality of first model outputs and the plurality of target outputs are of the same structure, domain, and types. For example, as it relates to types, first model outputs of sediment thickness and rock type may be compared to target outputs of sediment thickness and rock type but not compared to target outputs of sediment volume and rock type using the objective function.

In step 212, a decision is made to determine if the first residual calculated using the objective function is below a threshold. The decision may be made manually or automatically. In one embodiment, a residual threshold may be defined. If the first residual is below the residual threshold, the methodology (200) ends (214) and one iteration is complete. In another embodiment, stabilization of the residual after multiple iterations may be of interest in which case a residual difference threshold may be defined and calculated using the residual from the most recent iteration and the residual from the previous iteration. If the residual difference is below the residual difference threshold, the methodology (200) ends (214). Alternatively, if the residual is above the residual threshold or the residual difference threshold, the methodology (200) continues to step 216.

In step 216, an automated calibration algorithm is used to estimate a second set of variable values of the subsidence map. Automated calibration algorithms may be performed by a number of methods known to a person of ordinary skill in the art without departing from the scope of the invention. For example, automated calibration algorithms include a gradient descent algorithm and a non-linear least squares algorithm. If a regularization term is included in the objective function, the automated calibration algorithm may estimate the second set of variable values with more conservative number values relative to if the regularization term were excluded. Further, in another embodiment, the number value choices for the variable values for the automated calibration algorithm to update the second set of variable values with may be bounded. In this embodiment, bounds may restrict the number value choices for the variable values to be within physically realistic values or within a normalized range.

In step 218, the subsidence map is updated with the second set of variable values estimated by the automated calibration algorithm. If a pilot points method (300) was used in step 204 to define the subsidence map, a second set of interpolated values may now be updated using the fixed values and the second set of variable values along with an interpolation method as previously mentioned. Similarly, if a weighted linear combination method (302) was used in step 204 to define the subsidence map and interpolated values are present, a second set of interpolated values may now be updated using an interpolation method.

Now that the subsidence map with the second set of variable values has been defined, steps 206, 210, and 212 are repeated. In step 206, the subsidence map with the second set of variable values is input into the stratigraphic model to obtain second model outputs. In step 210, a second residual between the second model outputs and the target outputs is calculated using an objective function. In step 212, a decision is made to determine if the second residual is below a threshold. If the second residual is below the residual threshold or the residual difference threshold, the methodology (200) ends (214) and the second iteration is complete. If the second residual is above the residual threshold or the residual difference threshold, steps 216 and 218 are repeated. In step 216, the automated calibration algorithm is used to estimate a third set of variable values of the subsidence map. In step 218, the subsidence map is updated with the third set of variable values. This iterative process continues until the most recently calculated residual is below the residual threshold or the residual difference threshold and the methodology (200) ends (214).

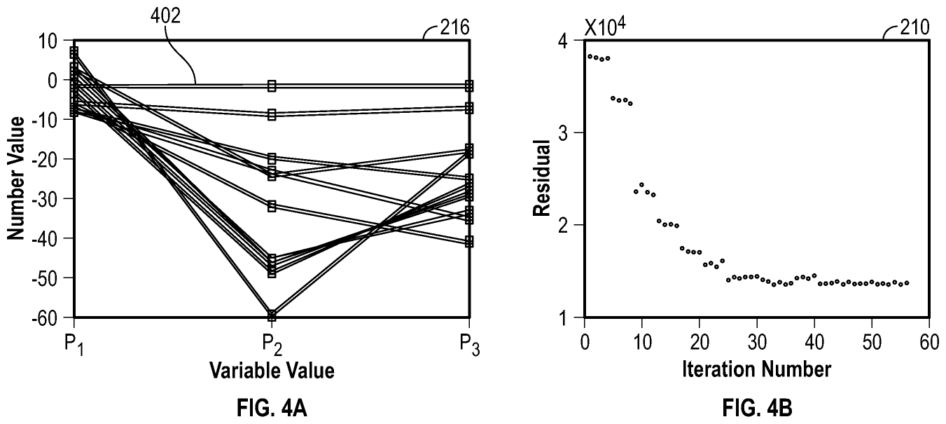

FIG. 4A shows number values for sets of variable values, P₁, P₂, and P₃, as iterations of the methodology (200) increase (216). The number values of P₁, P₂, and P₃ that are connected by a line (402) may be considered one set of variable values. In this embodiment, a weighted linear combination method (302) has been used to define and update a subsidence map where the subsidence map may be represented by:

P₁M₁+P₂M₂+P₃M₃ Equation (2).

FIG. 4B shows changes in the residual of an objective function as number values for sets of variable values, P₁, P₂, and P₃, change (210). In this embodiment, P₁, P₂, and P₃ take primarily negative number values to reduce the residual calculated by the objective function. By about iteration 25, the residual plateaus.

In some embodiments, it may be desirable to redefine variable values as fixed values within a subsidence map to reduce the computational cost of the methodology (200). This may be done by changing the number value of only one variable value within a set of variable values over each iteration of the methodology (200). As the methodology (200) is repeated iteratively, model outputs may be analyzed for changes. If model outputs are found to be insensitive to number value changes of the one variable value, the one variable value may be redefined as a fixed value. This process may be repeated for each variable value within the set of variable values. Further, this process may be performed on any set of the variable values of a subsidence map, i.e., the first set through the n^{th} set.

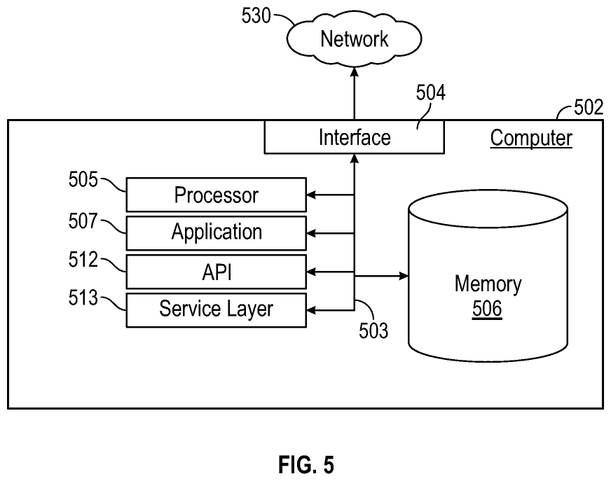

FIG. 5 depicts a block diagram of a computer system (502) used to provide computational functionalities associated with described machine learning networks, algorithms, methods, functions, processes, flows, and procedures as described in this disclosure, according to one or more embodiments. The illustrated computer (502) is intended to encompass any computing device such as a server, desktop computer, laptop/notebook computer, wireless data port, smart phone, personal data assistant (PDA), tablet computing device, one or more processors within these devices, or any other suitable processing device, including both physical or virtual instances (or both) of the computing device. Additionally, the computer (502) may include a computer that includes an input device, such as a keypad, keyboard, touch screen, or other device that can accept user information, and an output device that conveys information associated with the operation of the computer (502), including digital data, visual, or audio information (or a combination of information), or a GUI.

The computer (502) can serve in a role as a client, network component, a server, a database or other persistency, or any other component (or a combination of roles) of a computer system for performing the subject matter described in the instant disclosure. The illustrated computer (502) is communicably coupled with a network (530). In some implementations, one or more components of the computer (502) may be configured to operate within environments, including cloud-computing-based, local, global, or other environment (or a combination of environments).

At a high level, the computer (502) is an electronic computing device operable to receive, transmit, process, store, or manage data and information associated with the described subject matter. According to some implementations, the computer (502) may also include or be communicably coupled with an application server, e-mail server, web server, caching server, streaming data server, business intelligence (BI) server, or other server (or a combination of servers).

The computer (502) can receive requests over network (530) from a client application (for example, executing on another computer (502)) and responding to the received requests by processing the said requests in an appropriate software application. In addition, requests may also be sent to the computer (502) from internal users (for example, from a command console or by other appropriate access method), external or third-parties, other automated applications, as well as any other appropriate entities, individuals, systems, or computers.

Each of the components of the computer (502) can communicate using a system bus (503). In some implementations, any or all of the components of the computer (502), both hardware or software (or a combination of hardware and software), may interface with each other or the interface (504) (or a combination of both) over the system bus (503) using an application programming interface (API) (512) or a service layer (513) (or a combination of the API (512) and service layer (513). The API (512) may include specifications for routines, data structures, and object classes. The API (512) may be either computer-language independent or dependent and refer to a complete interface, a single function, or even a set of APIs. The service layer (513) provides software services to the computer (502) or other components (whether or not illustrated) that are communicably coupled to the computer (502). The functionality of the computer (502) may be accessible for all service consumers using this service layer. Software services, such as those provided by the service layer (513), provide reusable, defined business functionalities through a defined interface. For example, the interface may be software written in JAVA, C++, or other suitable language providing data in extensible markup language (XML) format or another suitable format. While illustrated as an integrated component of the computer (502), alternative implementations may illustrate the API (512) or the service layer (513) as stand-alone components in relation to other components of the computer (502) or other components (whether or not illustrated) that are communicably coupled to the computer (502). Moreover, any or all parts of the API (512) or the service layer (513) may be implemented as child or sub-modules of another software module, enterprise application, or hardware module without departing from the scope of this disclosure.

The computer (502) includes an interface (504). Although illustrated as a single interface (504) in FIG. 5, two or more interfaces (504) may be used according to particular needs, desires, or particular implementations of the computer (502). The interface (504) is used by the computer (502) for communicating with other systems in a distributed environment that are connected to the network (530). Generally, the interface (504) includes logic encoded in software or hardware (or a combination of software and hardware) and operable to communicate with the network (530). More specifically, the interface (504) may include software supporting one or more communication protocols associated with communications such that the network (530) or interface's hardware is operable to communicate physical signals within and outside of the illustrated computer (502).

The computer (502) includes at least one computer processor (505). Although illustrated as a single computer processor (505) in FIG. 4, two or more processors may be used according to particular needs, desires, or particular implementations of the computer (502). Generally, the computer processor (505) executes instructions and manipulates data to perform the operations of the computer (502) and any algorithms, methods, functions, processes, flows, and procedures as described in the instant disclosure.

The computer (502) also includes a memory (506) that holds data for the computer (502) or other components (or a combination of both) that can be connected to the network (530). For example, memory (506) can be a database storing data consistent with this disclosure. Although illustrated as a single memory (506) in FIG. 5, two or more memories may be used according to particular needs, desires, or particular implementations of the computer (502) and the described functionality. While memory (506) is illustrated as an integral component of the computer (502), in alternative implementations, memory (506) can be external to the computer (502).

The application (507) is an algorithmic software engine providing functionality according to particular needs, desires, or particular implementations of the computer (502), particularly with respect to functionality described in this disclosure. For example, application (507) can serve as one or more components, modules, applications, etc. Further, although illustrated as a single application (507), the application (507) may be implemented as multiple applications (507) on the computer (502). In addition, although illustrated as integral to the computer (502), in alternative implementations, the application (507) can be external to the computer (502).

There may be any number of computers (502) associated with, or external to, a computer system containing a computer (502), wherein each computer (502) communicates over network (530). Further, the term “client,” “user,” and other appropriate terminology may be used interchangeably as appropriate without departing from the scope of this disclosure. Moreover, this disclosure contemplates that many users may use one computer (502), or that one user may use multiple computers (502).

Although only a few example embodiments have been described in detail above, those skilled in the art will readily appreciate that many modifications are possible in the example embodiments without materially departing from this invention. Accordingly, all such modifications are intended to be included within the scope of this disclosure as defined in the following claims. In the claims, any means-plus-function clauses are intended to cover the structures described herein as performing the recited function(s) and equivalents of those structures. Similarly, any step-plus-function clauses in the claims are intended to cover the acts described here as performing the recited function(s) and equivalents of those acts. It is the express intention of the applicant not to invoke 35 U.S.C. § 112(f) for any limitations of any of the claims herein, except for those in which the claim expressly uses the words “means for” or “step for” together with an associated function.]

What is claimed is:

1. A method of calibrating a subsidence map, comprising:
selecting a stratigraphic model that represents a geological formation;
defining the subsidence map with a first set of variable values;
obtaining target outputs measured from the geological formation;
determining first model outputs from the stratigraphic model by inputting the subsidence map with the first set of variable values into the stratigraphic model; and
determining a first residual between the target outputs and the first model outputs using an objective function.

2. The method of claim 1, further comprising:
estimating a second set of variable values of the subsidence map using an automated calibration algorithm if the first residual is above a threshold;
updating the subsidence map with the second set of variable values;
determining second model outputs from the stratigraphic model by inputting the subsidence map with the second set of variable values into the stratigraphic model; and
determining a second residual between the target outputs and the second model outputs using the objective function.

3. The method of claim 1, further comprising:
changing one variable value in the subsidence map;
determining if model outputs are insensitive to changes in the one variable value; and
redefining the one variable value as a fixed value in the subsidence map.

4. The method of claim 1, wherein defining the subsidence map comprises using a pilot points method or a weighted linear combination method.

5. The method of claim 1, wherein a first set of interpolated values are determined from a set of fixed values and the first set of variable values.

6. The method of claim 2, wherein a second set of interpolated values are determined from a set of fixed values and the second set of variable values.

7. The method of claim 1, wherein the stratigraphic model predicts hydrocarbon reservoir position and composition within the geological formation.

8. The method of claim 1, wherein a type of the first model outputs and a type of the target outputs comprise at least one of: a sediment thickness map; a sediment gradient map; a sediment volume map; and a rock classification map.

9. The method of claim 8, wherein the type of the first model outputs and the type of the target outputs are identical.

10. The method of claim 1, wherein the objective function comprises at least one of a sum of square difference equation, a mean absolute difference equation, a least absolute difference equation, and a mean percentage difference equation.

11. The method of claim 1, wherein the automated calibration algorithm comprises at least one of a gradient descent algorithm and a non-linear least squares algorithm.

12. A non-transitory computer readable medium storing instructions executable by a computer processor, the instructions comprising functionality for:
receiving a stratigraphic model that represents a geological formation;
receiving a subsidence map with a first set of variable values;
receiving target outputs measured from the geological formation;
determining first model outputs from the stratigraphic model by inputting the subsidence map with the first set of variable values into the stratigraphic model; and
determining a first residual between the target outputs and the first model outputs using an objective function.

13. The non-transitory computer readable medium of claim 12, further comprising:
estimating a second set of variable values of the subsidence map using an automated calibration algorithm if the first residual is above a threshold;
updating the subsidence map with the second set of variable values;
determining second model outputs from the stratigraphic model by inputting the subsidence map with the second set of variable values into the stratigraphic model; and
determining a second residual between the target outputs and the second model outputs using the objective function.

14. The non-transitory computer readable medium of claim 12, further comprising:
changing one variable value in the subsidence map;
determining if model outputs are insensitive to changes in the one variable value; and
redefining the one variable value as a fixed value in the subsidence map.

15. The non-transitory computer readable medium of claim 12, wherein defining the subsidence map comprises using a pilot points method or a weighted linear combination method.

16. The non-transitory computer readable medium of claim 12, wherein the stratigraphic model predicts hydrocarbon reservoir position and composition within the geological formation.

17. The non-transitory computer readable medium of claim 12, wherein a type of the first model outputs and a type of the target outputs comprise at least one of: a sediment thickness map; a sediment gradient map; a sediment volume map; and a rock classification map.

18. The non-transitory computer readable medium of claim 12, wherein the objective function comprises at least one of a sum of square difference equation, a mean absolute difference equation, a least absolute difference equation, and a mean percentage difference equation.

19. The non-transitory computer readable medium of claim 12, wherein the automated calibration algorithm comprises at least one of a gradient descent algorithm and a non-linear least squares algorithm.

20. A system of calibrating a subsidence map, comprising:
a seismic acquisition system;
a geodetic surveying system; and
a computer system configured to:
receive a stratigraphic model based on geological formation data acquired using the seismic acquisition system;
receive a subsidence map with a first set of variable values based on topographical data acquired using the geodetic surveying system;
receive target outputs based on the geological formation data acquired using the seismic acquisition system;
determine first model outputs from the stratigraphic model by inputting the subsidence map with the first set of variable values into the stratigraphic model; and
determine a first residual between the target outputs and the first model outputs using an objective function.
